(19) United States
(12) Patent Application Publication
(10) Pub. No.: US 2024/0345473 A1
(43) Pub. Date: Oct. 17, 2024

(54) BLANK MASK AND METHOD OF FABRICATING THE SAME

(71) Applicant: SK enpulse Co., Ltd., Gyeonggi-do (KR)

(72) Inventors: Tae Wan KIM, Seoul (KR); In Kyun SHIN, Seoul (KR); Hyung Joo LEE, Seoul (KR)

(21) Appl. No.: 18/636,293

(22) Filed: Apr. 16, 2024

(30) Foreign Application Priority Data
Apr. 17, 2023 (KR) 10-2023-0050360

(51) Int. Cl. G03F 1/76

(52) U.S. Cl. CPC G03F 1/76

(57) ABSTRACT

A method of fabricating a blank mask. The method includes forming a light-shielding film on a light-transmissive substrate to form an optical substrate; forming a photoresist layer on the light-shielding film; and removing droplets, generated in the forming of the photoresist layer, from a side surface of the light-transmissive substrate, wherein the number of droplet-type adsorption, derived from the droplets, on the side surface of the light-transmissive substrate, is less than 3 per cm².

### CROSS-REFERENCE TO RELATED APPLICATIONS

This application claims priority under 35 U.S.C. § 119 to Korean Patent Application No. 10-2023-0050360 filed on Apr. 17, 2023 in the Korean Intellectual Property Office, the disclosure of which is incorporated herein by reference in its entirety.

### BACKGROUND

### Technical Field

Embodiments relate to a blank mask and a method of fabricating the blank mask.

### Background Art

Due to the high integration of semiconductor devices, etc., there is a demand for refinement of circuit patterns of semiconductor devices. Thereby, the importance of lithography technology, a technology that develops circuit patterns on the surface of a wafer using a photomask, is attracting more attention.

To develop refined circuit patterns, a shorter wavelength of the exposure light source used in an exposure process is required. As examples of exposure light sources recently used, there is an argon fluoride (ArF) excimer laser (wavelength: 193 nm), and the like.

Meanwhile, a photomask includes a binary mask, a phase shift mask, and the like. A binary mask includes a light-shielding layer pattern formed on a light-transmissive substrate. On the surface, where patterns are formed, of a binary mask, a light transmission part excluding a light-shielding layer transmits exposure light, and a light-shielding part including a light-shielding layer blocks the exposure light, exposing a pattern on a resist film of a wafer surface. Meanwhile, issues may occur in the fine pattern phenomenon due to light diffraction that occurs at the edges of a light transmission part during an exposure process as the pattern of a binary mask becomes finer.

As examples of a phase shift mask, there are a Levenson-type mask, an outrigger-type mask, and a half tone-type mask. Among these, a half tone-type phase shift mask has a pattern, which is made of a semi-transmissive film, formed on a light-transmissive substrate 20. On the patterned surface of the half tone-type phase shift mask, a light transmission part excluding a semi-transmissive layer transmits exposure light, and a semi-transmissive part including a semi-transmissive layer transmits attenuated exposure light. The attenuated exposure light has a phase difference compared to the exposure light that passed through the light transmission part. Accordingly, diffracted light occurring at the edge of the light transmission part is canceled out by exposure light transmitted through the semi-transmissive part, so that the phase shift mask can form a more elaborate fine pattern on a wafer surface.

Related documents are as follows:

(Patent Document 0001) Korean Patent Application Publication No. 10-2012-0057488

(Patent Document 0002) Korean Patent Application Publication No. 10-2014-0130420

### SUMMARY

Therefore, the present invention has been made in view of the above issues, and it is one object of the present invention to provide an apparatus for fabricating a blank mask that can provide a photomask having low defect occurrence, improved number of uses, and can provide high precision and a method of fabricating the blank mask.

In accordance with one aspect of the present invention, there is provided a method of fabricating a blank mask, the method including: forming a light-shielding film on a light-transmissive substrate to form an optical substrate; forming a photoresist layer on the light-shielding film; and removing droplets, generated in the forming of the photoresist layer, from a side surface of the light-transmissive substrate, wherein the number of droplet-type adsorption, derived from the droplets, on the side surface of the light-transmissive substrate, is less than 3 per cm².

The method of fabricating a blank mask according to one embodiment may further include seating the optical substrate on a chuck, wherein the forming of the photoresist layer includes: dropping a photoresist composition on the light-shielding film; rotating the optical substrate; and spraying compressed air between the optical substrate and the chuck, wherein the rotating of the optical substrate and the spraying of the compressed air are simultaneously performed.

The method of fabricating a blank mask according to another embodiment may further include seating the optical substrate on a chuck, wherein the forming of the photoresist layer includes dropping a photoresist composition on the light-shielding film; rotating the optical substrate; and applying vacuum between the side surface of the optical substrate and the chuck, wherein the rotating of the optical substrate and the applying of the vacuum are performed at the same time.

In the method of fabricating a blank mask according to another embodiment, the number of the droplet-type adsorption formed on a lower surface of the light-transmissive substrate may be less than 4 per cm².

In the method of fabricating a blank mask according to another embodiment, the chuck may include: a support part for supporting the optical substrate; and a guide part disposed on a side surface of the optical substrate, wherein in the rotating of the optical substrate, the optical substrate and the guide part are simultaneously rotated, and the compressed air is sprayed between the guide part and the side surface of the optical substrate.

In the method of fabricating a blank mask according to another embodiment, the chuck may include: a support part for supporting the optical substrate; and a guide part disposed on the side surface of the optical substrate, wherein in the rotating of the optical substrate, the optical substrate and the guide part are simultaneously rotated, and the vacuum is applied between the guide part and the side surface of the optical substrate.

In the method of fabricating a blank mask according to another embodiment, the optical substrate may include the droplet-type adsorption, the droplet-type adsorption may have an island shape, and the droplet-type adsorption may have a diameter ranging from about 0.01 μm to about 10 μm.

In the method of fabricating a blank mask according to another embodiment, the number of the droplet-type adsorption formed on a side surface of the light-transmissive substrate may range from about 0.05 per cm² to about 1 per cm².

In accordance with another aspect of the present invention, there is provided a blank mask, including: a light-transmissive substrate; a light-shielding film disposed on the light-transmissive substrate; and photoresist layer disposed on the light-shielding film and including a photosensitive resin, and, on a side surface of the light-transmissive substrate, the number of droplet-type adsorption including the photosensitive resin is less than 3 per cm².

In the blank mask according to another embodiment, the number of the droplet-type adsorption formed on a lower surface of the light-transmissive substrate may be less than 4 per cm².

In the blank mask according to another embodiment, the number of the droplet-type adsorption formed on a side surface of the light-transmissive substrate may be less than 2.5 per cm².

In the blank mask according to another embodiment, the number of the droplet-type adsorption formed on the side surface of the light-transmissive substrate may be less than 0.5 per cm².

In the blank mask according to another embodiment, the number of the droplet-type adsorption formed on a lower surface of the light-transmissive substrate may be less than 2 per cm².

In the blank mask according to another embodiment, the droplet-type adsorption may have a diameter ranging from 0.01 μm to 10 μm.

In accordance with yet another aspect of the present invention, there is provided a blank mask, including: a light-transmissive substrate; a light-shielding film disposed on the light-transmissive substrate; a photoresist layer disposed on the light-shielding film and including a photosensitive resin; and droplet-type adsorption formed on a side surface of the light-transmissive substrate, including the photosensitive resin and having an island shape, wherein the droplet-type adsorption formed on the side surface of the light-transmissive substrate has a density ranging from about 0.05 pieces per cm² to about 3 pieces per cm².

In the blank mask according to another embodiment, the droplet-type adsorption may be formed on a lower surface of the light-transmissive substrate, and the droplet-type adsorption formed on the lower surface of the light-transmissive substrate may have a density ranging from about 0.05 pieces per cm² to about 3 pieces per cm².

In the blank mask according to another embodiment, the droplet-type adsorption may include first droplet-type adsorption having a diameter ranging from about 0.01 μm or more and less than about 0.04 μm, and the number of the first droplet-type adsorption may range from about 0.05 per cm² to about 0.5 per cm².

In the blank mask according to another embodiment, the droplet-type adsorption may include second droplet-type adsorption having a diameter of about 0.04 μm or more and less than about 0.3 μm, and the number of the second droplet-type adsorption may be about 0.05 per cm² to about 0.5 per cm².

In the blank mask according to another embodiment, the droplet-type adsorption may include third droplet-type adsorption having a diameter of about 0.3 μm or more and less than about 3 μm, and the number of the third droplet-type adsorption may range from about 0.05 per cm² to about 0.5 per cm².

In the blank mask according to another embodiment, the droplet-type adsorption may include fourth droplet-type adsorption having a diameter of about 3 μm or more and less than about 10 μm, and the number of the fourth droplet-type adsorption may range from about 0.05 per cm² to about 0.5 per cm².

In the blank mask according to another embodiment, the droplet-type adsorption formed on a side surface of the light-transmissive substrate may have a density range from about 0.05 pieces per cm² to about 1 piece per cm².

A method of fabricating a blank mask according to another embodiment includes a step of removing droplets generated in the step of forming the photoresist layer. Accordingly, the method of fabricating a blank mask according to an embodiment can prevent the side surface and/or lower surface of the light-transmissive substrate from being contaminated by process by-products such as the droplets.

In particular, the method of fabricating a blank mask according to another embodiment can remove droplets, scattered from the photoresist composition for forming the photoresist layer, from the side surface of the light-transmissive substrate using compressed air or a vacuum.

Accordingly, the method of fabricating a blank mask according to another embodiment can effectively prevent the droplets from being adsorbed on the side surface and lower surface of the light-transmissive substrate.

Accordingly, the method of fabricating a blank mask according to another embodiment can provide a blank mask in which the number of droplet-type adsorption is less than 3 per cm² on the side surface of the light-transmissive substrate. In addition, the method of fabricating a blank mask according to an embodiment can provide a blank mask in which the number of the droplet-type adsorption is less than 4 per cm² on the lower surface of the light-transmissive substrate.

Accordingly, the method of fabricating a blank mask according to another embodiment can minimize optical distortion due to the droplet-type adsorption. Accordingly, the method of fabricating a blank mask according to another embodiment may provide improved optical performance.

In addition, since the method of fabricating a blank mask according to another embodiment suppresses the droplet-type adsorption as described above, an additional process of removing adsorbed droplets on the side surface and lower surface of the light-transmissive substrate is not used.

Accordingly, the method of fabricating a blank mask according to another embodiment can prevent the photoresist layer from being damaged by an additional process to remove the droplet-type adsorption.

Since the number of the droplet-type adsorption formed on the side surface and lower surface of the light-transmissive substrate of the blank mask according to another embodiment is less than 4 per cm², optical distortion can be minimized, and improved optical performance can be provided.

### BRIEF DESCRIPTION OF DRAWINGS

FIG. 1 is a schematic view illustrating an apparatus for fabricating a blank mask according to one embodiment.

FIG. 2 is a perspective view illustrating a chuck according to another embodiment.

FIG. 3 illustrates an upper surface of the chuck according to another embodiment.

FIG. 4 is a sectional view illustrating a cross-section of the chuck.

FIG. 5 illustrates an enlarged cross-sectional view of part A of FIG. 4.

FIG. 6 illustrates a process by which process by-products are removed according to another embodiment.

FIG. 7 illustrates a process by which process by-products are removed according to another embodiment.

FIG. 8 is a schematic view illustrating an apparatus for fabricating a blank mask according to still another embodiment.

FIG. 9 illustrates a process by which process by-products are removed according to still another embodiment.

FIG. 10 illustrates a sectional view illustrating a cross-section of an optical substrate according to one embodiment.

FIG. 11 illustrates a sectional view illustrating a cross-section of an optical substrate according to another embodiment.

FIG. 12 illustrates a sectional view illustrating a cross-section of an optical substrate according to still another embodiment.

FIG. 13 illustrates a sectional view illustrating a cross-section of a blank mask according to one embodiment.

FIG. 14 is a sectional view illustrating a cross-section of a photomask according to another embodiment.

FIG. 15 illustrates a portion of a side surface of a light-transmissive substrate according to another embodiment.

FIG. 16 is a sectional view illustrating a cross-section taken along line B-B′ of FIG. 15.

FIG. 17 is a sectional view illustrating a portion of a bottom of a light-transmissive substrate according to another embodiment.

### DETAILED DESCRIPTION

Hereinafter, embodiments will be described in detail such that those skilled in the art can make and used the invention. However, the embodiments may be implemented in various different forms and the present invention is not limited to embodiments described herein.

The terms “about,” “substantially,” and the like used in this specification are used to mean at or close to a presented numerical value when manufacturing and material tolerances in the stated meaning are presented, and are provided to aid understanding of the embodiments.

Throughout this specification, the term “a combination thereof” refers to a mixture or combination of one or more elements selected from the group consisting of components, and to include one or more selected from the group consisting of the components.

Throughout this specification, the expression “A and/or B” means “A, B, or A and B”. In this specification, “B is located on A” means “B is located on A” or “B is located on A with another layer located therebetween”, and is not interpreted as limited to B being positioned in contact with the surface of A.

In this specification, singular expressions are interpreted to include singular or plural as interpreted in context, unless otherwise specified.

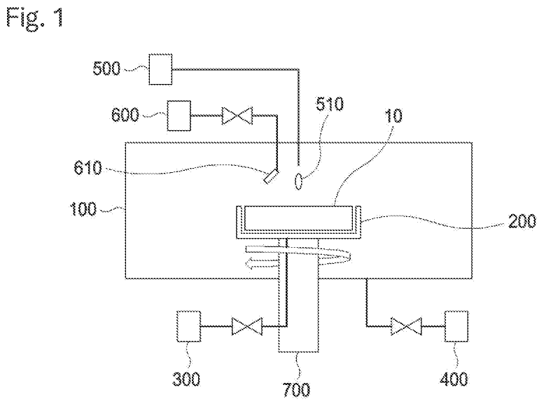

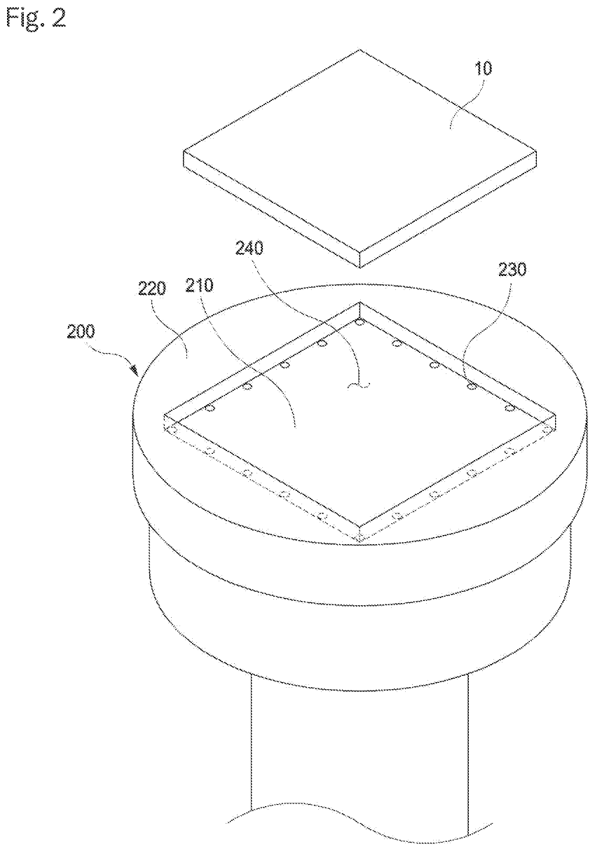

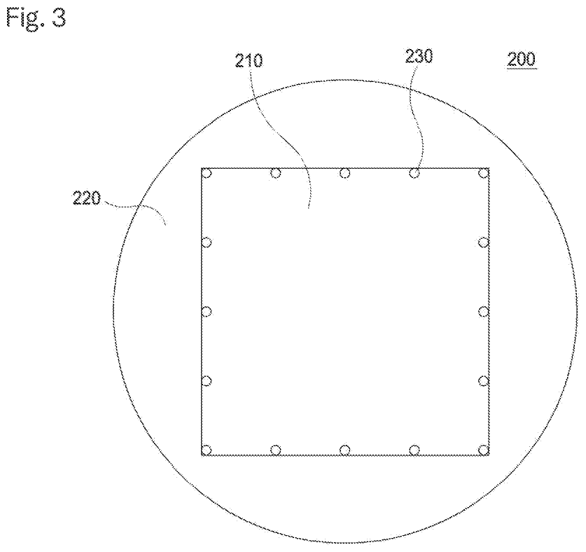

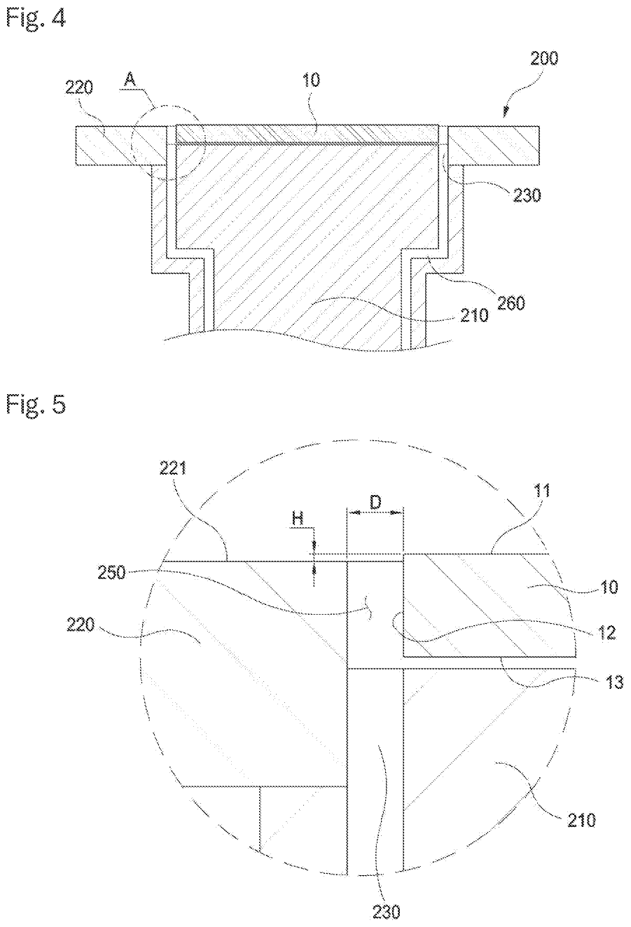

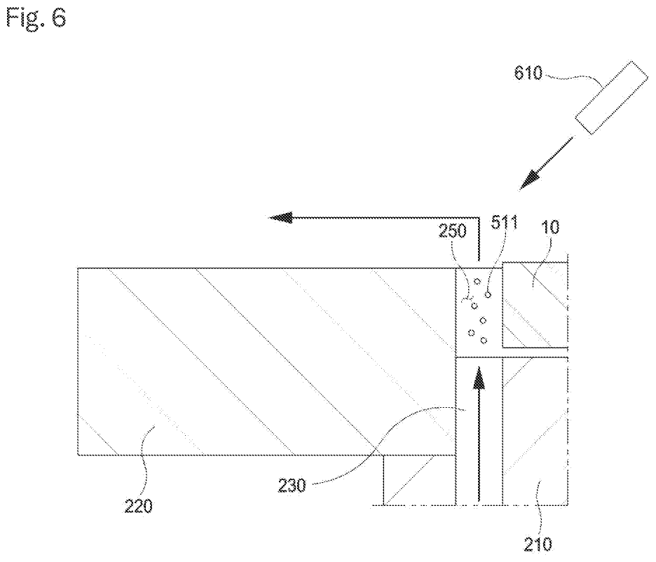

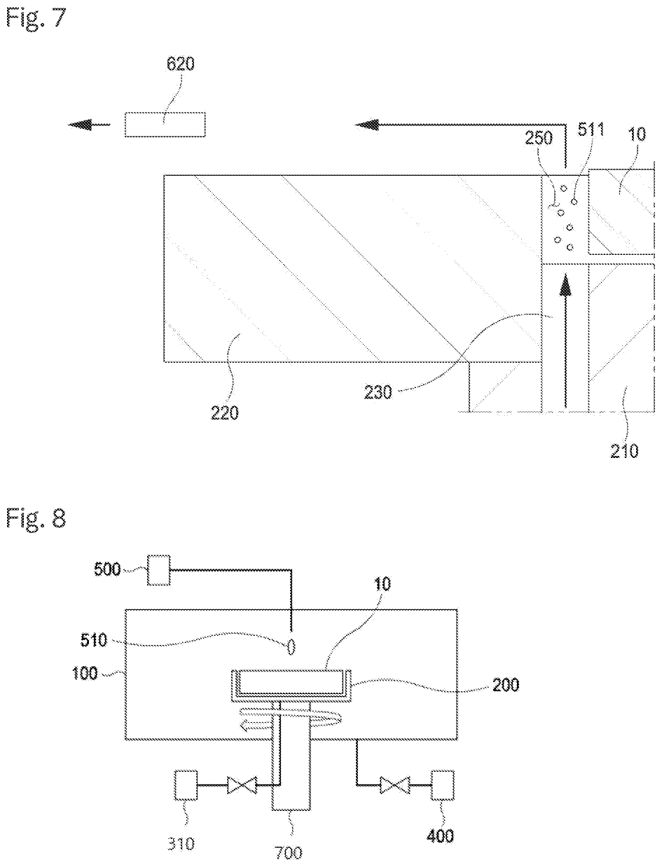

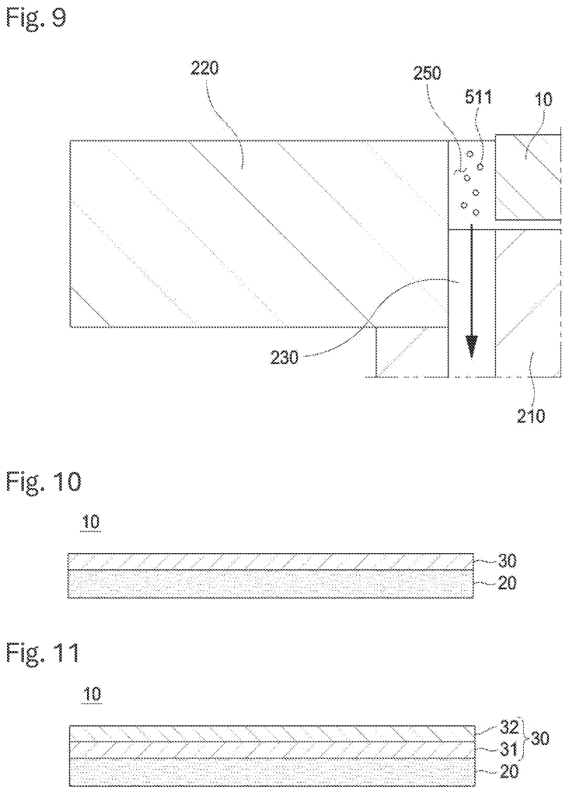

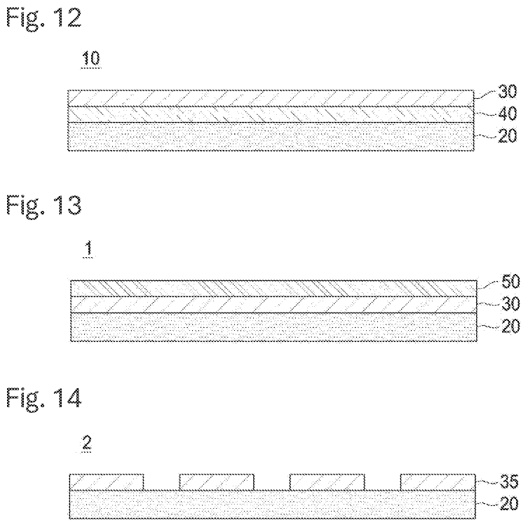

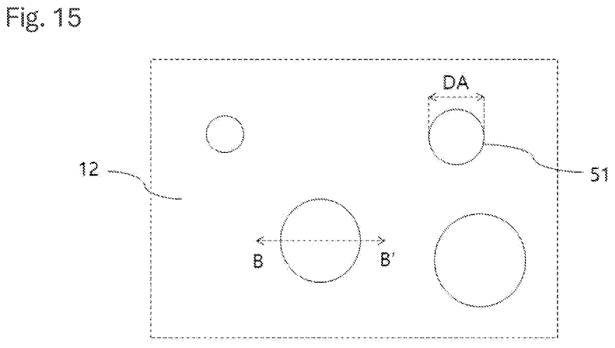

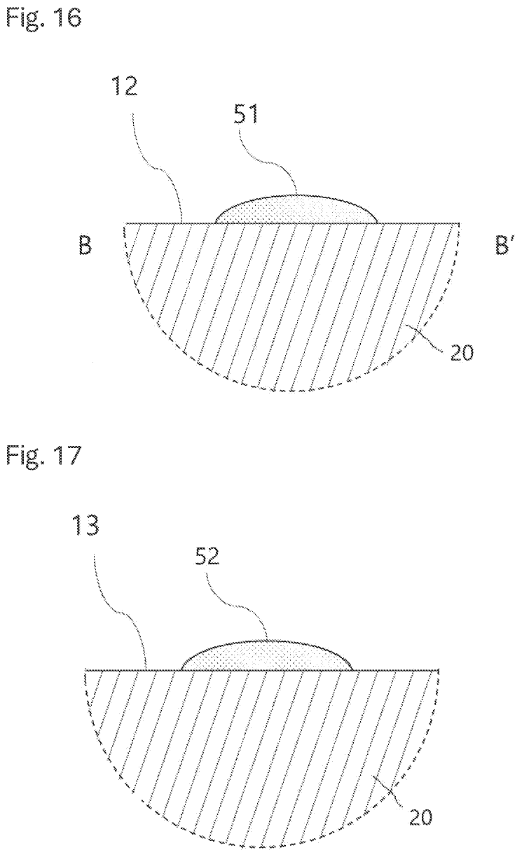

FIG. 1 is a schematic view illustrating an apparatus for fabricating a blank mask according to one embodiment. FIG. 2 is a perspective view illustrating a chuck according to another embodiment. FIG. 3 illustrates an upper surface of the chuck according to another embodiment. FIG. 4 is a sectional view illustrating a cross-section of the chuck. FIG. 5 illustrates an enlarged cross-sectional view of part A of FIG. 4. FIG. 6 illustrates a process by which process by-products are removed according to one embodiment. FIG. 7 illustrates a process by which process by-products are removed according to another embodiment. FIG. 8 is a schematic view illustrating an apparatus for fabricating a blank mask according to still another embodiment. FIG. 9 illustrates a process by which process by-products are removed according to still another embodiment. FIG. 10 illustrates a sectional view illustrating a cross-section of an optical substrate according to one embodiment. FIG. 11 illustrates a sectional view illustrating a cross-section of an optical substrate according to another embodiment. FIG. 12 illustrates a sectional view illustrating a cross-section of an optical substrate according to still another embodiment. FIG. 13 illustrates a sectional view illustrating a cross-section of a blank mask according to another embodiment. FIG. 14 is a sectional view illustrating a cross-section of a photomask according to one embodiment. FIG. 15 illustrates a portion of a side surface of a light-transmissive substrate according to another embodiment. FIG. 16 is a sectional view illustrating a cross-section taken along line B-B′ of FIG. 15. FIG. 17 is a sectional view illustrating a portion of a bottom of a light-transmissive substrate according to an embodiment.

Referring to FIG. 1, the apparatus for fabricating a blank mask according to one embodiment includes a chamber 100, a chuck 200, a first air pump 300, an exhaust part 400, a photoresist resin composition supply part 500, an air sweep part 610, a second air pump 600 and a spindle motor 700.

The chamber 100 contains the chuck 200. The chamber 100 may contain an optical substrate 10 for fabricating a blank mask. The inside of the chamber 100 may be isolated from the outside. The interior of the chamber 100 may be sealed. The pressure inside the chamber 100 may be lower than atmospheric pressure.

In addition, the chamber 100 may include a door or cover that can be opened or closed. A heater that can control the temperature inside the chamber 100 may be provided in the chamber 100.

Referring to FIGS. 2 to 7, the chuck 200 includes a support part 210, a guide part 220 and a by-product removal part 230.

The support part 210 may support the guide part 220 and the by-product removal part 230. The support part 210 supports the optical substrate 10. The support part 210 may be disposed under the optical substrate 10.

The support part 210 may temporarily fix the optical substrate 10. The support part 210 may temporarily fix the optical substrate 10 by a vacuum (sub-atmospheric pressure) or an electrostatic force.

The guide part 220 may be connected to the support part 210. The guide part 220 may be formed integrally with the support part 210. The guide part 220 may be disposed on a side surface 12 of the optical substrate 10 when the optical substrate 10 is placed on support part 210. The guide part 220 may surround the side surface 12 of the optical substrate 10.

Due to the support part 210 and the guide part 220, a receiving part 240 for accommodating the optical substrate 10 may be formed. That is, the support part 210 may be disposed against a lower surface 13 of the optical substrate 10, and the guide part 220 may be disposed adjacent the side surface 12 of the optical substrate 10, thereby constituting the receiving part 240.

The receiving part 240 may correspond to the planar shape of the optical substrate 10. The planar shape of the receiving part 240 may be substantially similar to the planar shape of the optical substrate 10. The planar shape of the optical substrate 10 may be square, and the planar shape of the receiving part 240 may also be square.

The outline of the guide part 220 may have a circular shape. The guide part 220 and the support part 210 may have a circular shape. These shapes in the present invention are not limited to square and circular shapes.

The by-product removal part 230 may be formed on the support part 210. The by-product removal part 230 may be formed on the guide part 220. The by-product removal part 230 may be formed on a part where the support part 210 and the guide part 220 meet. The by-product removal part 230 may be formed over the support part 210 and the guide part 220.

The by-product removal part 230 may be formed in a region corresponding to an edge part of the optical substrate 10. The by-product removal part 230 may be formed along the edge part of the support part 210.

The by-product removal part 230 may include a plurality of holes that spray gas. The holes may extend downward. The diameter of the holes may range from about 0.5 mm to about 2 mm. An interval between the holes may range from about 10 mm to 100 mm.

The by-product removal part 230 may be disposed under a space 250 between the guide part 220 and the side surface 12 of the optical substrate 10. The by-product removal part 230 may be disposed to correspond to a region 250 between an inner side surface of the guide part 220 and the side surface 12 of the optical substrate 10.

The guide part 220 and the side surface 12 of the optical substrate 10 may be spaced apart from each other by a certain interval. As shown in FIG. 5, a distance D between the inner side surface of the guide part 220 and the side surface 12 of the optical substrate 10 may range from about 0.01 mm to about 1 mm. An interval D between the guide part 220 and the side surface 12 of the optical substrate 10 may be less than about 1 mm.

Since the guide part 220 and the side surface 12 of the optical substrate 10 have the above-described interval D, the inflow of the process by-products 511 into the space 250 between the guide part 220 and the optical substrate 10 may be suppressed.

In addition, since the holes have a diameter and interval within the above-described ranges, the by-product removal part 230 may spray compressed air or apply a vacuum to a space between the guide part 220 and the optical substrate 10. Accordingly, since the holes have the above-described diameter and interval, the by-product removal part 230 may remove the process by-products 511 flowing into the space 250 between the guide part 220 and the optical substrate 10, as illustrated in FIG. 6.

As shown in FIG. 5, a height difference H between the upper surface 221 of the guide part 220 and the upper surface 11 of the optical substrate 10 may be less than about 1 mm. The height difference H between the upper surface 221 of the guide part 220 and the upper surface 11 of the optical substrate 10 may range from less than about 0.1 mm to about 1 mm. The upper surface 221 of the guide part 220 may be lower than the upper surface 11 of the optical substrate 10.

When the height difference H between the top surface 221 of the guide part 220 and the top surface 11 of the optical substrate 10 is the same as the above-described difference, the process by-products 511 may be discharged when the optical substrate 10 is spin-coated with a photoresist resin composition.

The by-product removal part 230 may be connected to the first air pump 300. The by-product removal part 230 may be connected to the first air pump 300 through a flow path 260. The by-product removal part 230 may receive compressed air, generated by the first air pump 300, through the flow path 260 and push the process by-products 511, as shown in FIG. 6. That is, the process by-products 511 may be ejected upward from the by-product removal part 230 by the first air pump 300.

That is, the compressed air is generated from the first air pump 300 and sprayed upward from the by-product removal part 230 through the flow path 260. Accordingly, process by-products flowing between the optical substrate 10 and the guide part 220 may be discharged upward.

In addition, the compressed air may be continuously sprayed upward from the by-product removal part 230. Accordingly, the inflow of the process by-products into the space 250 between the side surface of the optical substrate 10 and the guide part 220 may be fundamentally suppressed. The process by-products 511 may include fine particles. The fine particles may be formed by scattering of the photoresist resin composition. The process by-products 511 may be droplets formed when the photoresist resin composition scatters. That is, the fine particles may be the droplets.

In addition, the droplets may include the photoresist resin composition. The droplets may contain substantially the same material as the material for forming the photoresist layer. The droplets and the photoresist layer may have substantially the same composition.

The fine particles may have a particle diameter of less than about 10 μm. The fine particles may have a particle diameter ranging from about 1 μm to about 10 μm.

A spraying speed of the by-product removal part 230 may range from about 0.3 ml/s to about 100 ml/s. The spraying speed of the by-product removal part 230 may range from about 0.4 ml/s to about 20 ml/s. The spraying speed of the by-product removal part 230 may range from about 0.5 ml/s to about 10 ml/s. Accordingly, the by-product removal part 230 may remove the process by-products 511 contained in the space 250 between the guide part 220 and the optical substrate 10.

The first air pump 300 may be connected to the by-product removal part 2301. The first air pump 300 may be connected to the by-product removal part 230 through the flow path. The first air pump 300 may supply the compressed air to the by-product removal part 230.

The exhaust part 400 may exhaust gas inside the chamber 100. In addition, the exhaust part 400 may discharge a photoresist composition remaining after being coated on the optical substrate 10. The exhaust part 400 may discharge a photoresist resin composition scattered to the side of the chuck 200.

The photoresist resin composition supply part 500 may supply a photoresist resin composition 510 to a top surface of the optical substrate 10. The photoresist resin composition 510 may include a spray nozzle disposed in the chamber 100. Through the spray nozzle, the photoresist resin composition 510 may be dropped onto the optical substrate 10. That is, the photoresist resin composition supply part 500 may spray the photoresist resin composition 510 to the top surface of the optical substrate 10.

The chuck 200 and the optical substrate 10 may be rotated at the same time. That is, the guide part 220 and the optical substrate 10 may be rotated at the same time. In addition, the photoresist resin composition supply part 500 may supply the photoresist resin composition 510 to the upper surface of the optical substrate 10 while the guide part 220 and the optical substrate 10 are rotated at the same time.

In addition, the by-product removal part 230 may remove the process by-products 511 contained in the space 250 between the guide part 220 and the optical substrate 10 while the guide part 220 and the optical substrate 10 are rotated at the same time.

As shown in FIGS. 1 and 6, the air sweep part 610 may be disposed on the optical substrate 10. The air sweep part 610 may be disposed above the chuck 200.

The air sweep part 610 may spray the guided air toward an outer part of the optical substrate 10. The air sweep part 610 may spray the guided air from the center of the optical substrate 10 toward the outside. The air sweep part 610 may spray the guided air outward and downward against the upper surface of the optical substrate 10. That is, the air sweep part 610 may spray the guided air to the outside of the optical substrate 10.

Accordingly, the process by-products ejected from a space between the side surface of the optical substrate 10 and the guide part 220 may flow outward. That is, the air sweep part 610 may guide the flow of air ejected upward from the space 250 between the side surface of the optical substrate 10 and the guide part 220 to the outside of the optical substrate 10.

Accordingly, the air sweep part 610 may prevent the upper surface of the optical substrate 10 from being contaminated by the ejected process by-products.

The second air pump 600 may be connected to the air sweep part 610. The second air pump 600 may supply the guided air to the air sweep part 610.

The second air pump 600 may be omitted, and the air sweep part 610 may be connected to the first air pump 300. The air sweep part 610 may receive the guided air from the first air pump 300.

As shown in FIG. 7, the air sweep part 610 may include a suction nozzle 620. The suction nozzle 620 may extend from the exhaust part 400 and may be placed on one side of the chuck 200. The suction nozzle may vacuum exhaust the photoresist composition scattering laterally from the chuck 200.

In addition, the air sweep part 610 may guide the flow of compressed air ejected from the space 250 between the side surface of the optical substrate 10 and the guide part 220 to the outside of the optical substrate 10. Accordingly, the air sweep part 610 may prevent the upper surface of the optical substrate 10 from being contaminated by the ejected process by-products.

The spindle motor 700 may be connected to the chuck 200. The spindle motor 700 may rotate the chuck 200 at high speed. The chuck 200 may rotate at a speed ranging from about 500 rpm to about 7000 rpm by the spindle motor 700.

As the chuck 200 rotates, a centrifugal force may be applied to the dropped photoresist resin composition, and a photoresist resin composition layer may be formed to a uniform thickness on the optical substrate 10.

The by-product removal part 230 may push the process by-products 511 through the compressed air. Accordingly, the by-product removal part 230 may remove the process by-products 511 in the form of fine particles flowing between the guide part 220 and the side surface 12 of the optical substrate 10. That is, the by-product removal part 230 may remove the process by-products 511 in the form of fine particles flowing between the guide part 220 and the side surface 12 of the optical substrate 10 while the guide part 220 and the optical substrate 10 rotate at the same time.

In particular, since the by-product removal part 230 is disposed to correspond to a region between the side surface 12 of the optical substrate 10 and the guide part 220, the process by-products 511 may be removed.

Accordingly, the apparatus for fabricating a blank mask according to one embodiment may minimize contamination by the process by-products 511. In particular, a blank mask according to one embodiment may prevent the process by-products 511 from contaminating the side surface 12 of the optical substrate 10 and the lower surface 13 thereof.

Referring to FIG. 8, an apparatus for fabricating a blank mask according to still another embodiment may further include a vacuum part 310. In addition, an apparatus for fabricating a blank mask according to another embodiment may not include the air sweep part.

A vacuum part 300 may be connected to the by-product removal part 230. The vacuum part 300 may be connected to the by-product removal part 230 through the flow path 260. The vacuum part 300 may apply a vacuum to the by-product removal part 230. The vacuum part 300 may vacuum exhaust and filter the process by-products 511. The vacuum part 300 may discharge the process by-products 511.

As shown in FIG. 9, the by-product removal part 230 may exhaust the process by-products 511 through the vacuum. Accordingly, the by-product removal part 230 may remove the process by-products 511 in the form of fine particles flowing between the guide part 220 and the side surface 12 of the optical substrate 10.

In particular, when the by-product removal part 230 is placed to correspond to a corner where the side surface 12 of the optical substrate 10 and the lower surface 13 thereof meet, the process by-products 511 may be removed.

Accordingly, the apparatus for fabricating a blank mask according to another embodiment may minimize contamination by the process by-products 511. In particular, a blank mask according to one embodiment may prevent the process by-products 511 from contaminating the side surface 12 of the optical substrate 10 and the lower surface 13 thereof.

The by-product removal part 230 may receive vacuum pressure, generated by the vacuum part 300, through the flow path 260 and may vacuum exhaust the process by-products 511. That is, the process by-products 511 may be removed by the vacuum part 300 through the by-product removal part 230 and the flow path 260.

In particular, while the guide part 220 and the optical substrate 10 rotate at the same time, the by-product removal part 230 may receive a vacuum, generated by the vacuum part 300, through the flow path 260, and the process by-products 511 may be vacuum exhausted between the guide part 220 and the optical substrate 10.

An exhaust speed of the by-product removal part 230 may range from about 1 ml/s to about 100 ml/s. Accordingly, the by-product removal part 230 may remove the process by-products 511 contained in the space between the guide part 220 and the optical substrate 10.

The blank mask according to another embodiment may be produced according to the following fabrication process.

First, referring to FIG. 19, the optical substrate 10 may be provided. The optical substrate 10 includes a light-transmissive substrate 20; and a light-shielding film 30 placed on the light-transmissive substrate 20.

The light-transmissive substrate 20 may have optical transparency to exposure light. The light-transmissive substrate 20 may have a transmittance of greater than about 85% for exposure light having a wavelength of about 193 nm. The transmittance of the light-transmissive substrate 20 may be greater than about 87%. The transmittance of the light-transmissive substrate 20 may be less than 99.99%. The light-transmissive substrate 20 may include a synthetic quartz substrate. In this case, the light-transmissive substrate 20 may suppress the attenuation of transmitted light.

Since the light-transmissive substrate 20 has surface characteristics such as appropriate flatness and appropriate illuminance, it may suppress distortion of transmitted light.

The light-shielding film 30 may be disposed on a top side of the light-transmissive substrate 20.

The light-shielding film 30 may at least selectively block exposure light incident on a bottom side of the light-transmissive substrate 20.

In addition, when a phase shift film 40, etc. Is disposed between the light-transmissive substrate 20 and the light-shielding film 30 as shown in FIG. 10, the light-shielding film 30 may be used as an etching mask in a process of etching the phase inversion film 40, etc. According to a pattern shape.

The light-shielding film 30 may include a transition metal and at least one of oxygen and nitrogen.

The light-shielding film 30 may include chromium, oxygen, nitrogen and carbon. The content of each element in the entire light-shielding film 30 may vary in the thickness direction. The content of each element in the entire light-shielding film 30 may differ by layer in the case of a multi-layered light-shielding film 30.

The light-shielding film 30 may include chromium in a content ranging from about 44 atom % to about 60 atom %. The light-shielding film 30 may include chromium in a content ranging from about 47 atom % to about 57 atom %.

The light-shielding film 30 may include carbon in a content ranging from about 5 atom % to 30 atom %. The light-shielding film 30 may include carbon in a content ranging from about 7 atom % to about 25% atom%.

The light-shielding film 30 may include nitrogen in a content ranging from about 3 atom % to about 20 atom %. The light-shielding film 30 may include nitrogen in a content ranging from about 5 atom % to about 15 atom %.

The light-shielding film 30 may include oxygen in a content ranging from about 20 atom % to about 45 atom %. The light-shielding film 30 may include oxygen in a content ranging from about 25 atom % to about 40 atom %.

In one embodiment, the light-shielding film 30 may have sufficient extinction properties to attenuate substantially all transmission of for example light having a wavelength of about 193 nm though the light-shielding film 20.

As shown in FIG. 11, the light-shielding film 30 may include a first light-shielding layer 31 and a second light-shielding layer 32 which respectively include a transition metal and at least one of oxygen and nitrogen.

The second light-shielding layer 32 may include a transition metal in a content ranging from about 50 at % to about 80 at %. The second light-shielding layer 32 may include a transition metal in a content ranging from about 55 at % to about 75 at %. The second light-shielding layer 32 may include a transition metal in a content ranging from about 60 at % to about 70 at %. In the second light-shielding layer 32, the sum of the oxygen content and the nitrogen content may range from about 10 at % to about 30 at %. In the second light-shielding layer 32, the sum of the oxygen content and the nitrogen content may be about 15 at % to about 25 at %. The second light-shielding layer 32 may include nitrogen in a content ranging from about 5 at % to about 15 at %. The second light-shielding layer 32 may include nitrogen in a content ranging from about 7at % to about 13 at %.

The first light-shielding layer 31 may include a transition metal in a content v about 30 at % to about 60 at %. The first light-shielding layer 31 may include a transition metal in a content ranging from about 35 at % to about 55 at %. The first light-shielding layer 31 may include a transition metal in a content ranging from about 40 at % to about 50 at %. In the first light-shielding layer 31, the sum of the oxygen content and the nitrogen content may range from about 40 at % to about 70 at %. In the first light-shielding layer 31, the sum of the oxygen content and the nitrogen content may range from about 45 at % to about 65 at %. In the first light-shielding layer 31, the sum of the oxygen content and the nitrogen content may range from about 50 at % to about 60 at %.

The first light-shielding layer 31 may include oxygen in a content ranging from about 20 at % to about 37 at %. The first light-shielding layer 31 may include oxygen in a content ranging from about 23 at % to about 33 at %. The first light-shielding layer 31 may include oxygen in a content ranging from about 25 at % to about 30 at %. The first light-shielding layer 31 may include nitrogen in a content ranging from about 20 at % to about 35 at %. The first light-shielding layer 31 may include nitrogen in a content ranging from about 26 at % to about 33 at %. The first light-shielding layer 31 may include nitrogen in a content ranging from about 26 at % to about 30 at %.

The transition metal may include at least one of Cr, Ta, Ti and Hf. The transition metal may be Cr.

In this case, the first light-shielding layer 31 may help the light-shielding film 30 have excellent extinction properties.

The thickness of the first light-shielding layer 31 may be about 250 Å to about 650 Å. The thickness of the first light-shielding layer 31 may be about 350 Å to about 600 Å. The thickness of the first light-shielding layer 31 may be about 400 Å to about 550 Å. In this case, the first light-shielding layer 31 may help the light-shielding film 30 effectively block exposure light.

The thickness of the second light-shielding layer 32 may be about 30 Å to about 200 Å. The thickness of the second light-shielding layer 32 may range from about 30 Å to about 100 Å. The thickness of the second light-shielding layer 32 may range from about 40 Å to about 80 Å. In this case, the second light-shielding layer 32 may improve the extinction characteristics of the light-shielding film 30 and may help to more precisely control the side surface profile of a light-shielding pattern film 35 formed during patterning of the light-shielding film 30.

A ratio of the thickness of the second light-shielding layer 32 to the thickness of the first light-shielding layer 31 may range from about 0.05 to about 0.3. The ratio of the thickness of the second light-shielding layer 32 to the thickness of the first light-shielding layer 31 may range from e about 0.07 to about 0.25. The ratio of the thickness of the second light-shielding layer 32 to the thickness of the first light-shielding layer 31 may range from about 0.1 to about 0.2.

In this case, the light-shielding film 30 has sufficient extinction characteristics and may more precisely control the side surface profile of a light-shielding pattern film 35 formed during patterning of the light-shielding film 30.

The content of a transition metal in the second light-shielding layer 32 may be larger than the content of a transition metal in the first light-shielding layer 31.

To more precisely control the side surface profile of the light-shielding pattern film 35 formed by pattering the light-shielding film 30 and to ensure that the reflectance of the surface of the light-shielding film 30 for inspection light in defect inspection has a value suitable for inspection, the second light-shielding layer 32 may be required to have a larger transition metal content than the first light-shielding layer 31.

In this case, recovery, recrystallization, and grain growth may occur in a transition metal contained in the second light-shielding layer 32 during the heat treatment of the formed light-shielding film 30. If grain growth occurs in the second light-shielding layer 32 containing a high content of a transition metal, the illuminance characteristics of the surface of the light-shielding film 30 may excessively change due to excessively grown transition metal particles. This may cause an increase in the number of pseudo defects detected when defects on the surface of the light-shielding film 30 are inspected with high sensitivity.

The light-shielding film 30, may have a transmittance ranging from about 1% to about 2% for light with a wavelength of 193 nm. The light-shielding film 30 may have a transmittance ranging from about 1.3% to about 2% for light with a wavelength of 193 nm. The light-shielding film 30 may have a transmittance ranging from about 1.4% to about 2% for light with a wavelength of 193 nm.

The light-shielding film 30 may have an optical density ranging from about 1.8 to about 3. The light-shielding film 30 may have an optical density ranging from about 1.9 to about 3.

In this case, a thin film containing the light-shielding film 30 may effectively suppress the transmission of exposure light.

As shown in FIG. 12, the optical substrate 10 may further include the phase shift film 40.

The phase shift film 40 may be disposed between the light-transmissive substrate 20 and the light-shielding film 30. The phase shift film 40 may be a thin film that attenuates the light intensity of penetrating exposure light and adjusts a phase difference to substantially suppress the diffracted light occurring at the edge of a pattern.

The phase shift film 40 may have a phase difference ranging from about 170° to about190° for light with a wavelength of 193 nm. The phase shift film 40 may have a phase difference ranging from about 175° to about 185° for light with a wavelength of 193 nm.

The phase shift film 40 may have a transmittance ranging from about 3% to about 10% for light with a wavelength of 193 nm. The phase shift film 40 may have a transmittance ranging from about 4% to about 8% for light with a wavelength of 193 nm. In this case, the resolution of a photomask 200 containing the phase shift film 40 may be improved.

The phase shift film 40 may include a transition metal and silicon. The phase shift film 40 may include a transition metal, silicon, oxygen and nitrogen. The transition metal may be molybdenum.

A hard mask may be placed on the light-shielding film 30. The hard mask may function as an etching mask film when etching the pattern of the light-shielding film 30. The hard mask may include silicon, nitrogen and oxygen.

A method of fabricating the optical substrate 10 includes a step of forming the light-shielding film 30 on the light-transmissive film. The light-shielding film 30 may be formed by a sputtering process.

After the sputtering process proceeds, a heat treatment process may proceed.

The heat treatment step may be performed at about 200° C. to about 400° C.

The heat treatment step may be performed for about 5 minutes to about 30 minutes.

In addition, the method of fabricating the optical substrate 10 may further include a step of cooling the light-shielding film 30 that has been subjected to the heat treatment process.

The sputtering target may be selected considering the composition of the light-shielding film 30 to be formed. The sputtering target may be applied with a single target containing a transition metal. The sputtering target may be applied with two or more targets including one target containing a transition metal. The target containing a transition metal may contain 90 atom % or more of a transition metal. The target containing a transition metal may contain 95 atom % or more of a transition metal. The target containing a transition metal may include 99 atom % of a transition metal.

The transition metal may include at least one of Cr, Ta, Ti and Hf. The transition metal may include Cr.

The atmospheric gas may include inert gas, reactive gas and sputtering gas. The inert gas does not contain elements constituting a formed thin film. The reactive gas may contain elements formed into the thin film.

The sputtering gas ionizes in a plasma atmosphere and collides with a target. The inert gas may include helium.

The reactive gas may include a gas containing nitrogen element. The gas containing the nitrogen element may be, for example, N₂, NO, NO₂, N₂O, N₂O₃, N₂O₄, N₂O₅ or the like. The reactive gas may include a gas containing an oxygen element.

The gas containing the oxygen element may be, for example, O₂. The reactive gas may include a gas containing nitrogen element and a gas containing oxygen element. The reactive gas may include a gas containing both nitrogen element and oxygen element. The gas containing both the nitrogen element and the oxygen element may be, for example, NO, NO₂, N₂O, N₂O₃, N₂O₄, N₂O₅, or the like.

In addition, the reactive gas containing carbon and oxygen may be CO₂.

The sputtering gas may be Ar gas.

A power source that applies power to the sputtering target may be either DC power or RF power.

Next, the cooled light-shielding film 30 may be cleaned. The cleaning process may include an ultraviolet irradiation process and/or a rinse process.

The ultraviolet irradiation process may include a step of irradiating ultraviolet rays to the light-shielding film 30.

The rinse process includes a step of treating the light-shielding film 30 with a cleaning solution. The cleaning solution may include at least one of deionized water, hydrogen water, ozone water and carbonated water. The cleaning solution may include the carbonated water.

The optical substrate 10 may be disposed in the chamber 100. The optical substrate 10 may be temporarily fixed to the chuck 200. The optical substrate 10 may be disposed in the receiving part. The optical substrate 10 may be seated on the chuck 200.

As shown in FIG. 13, the method of fabricating the blank mask according to one embodiment includes a step of forming a photoresist layer 50 on the optical substrate 10.

To form the photoresist layer 50, the inside of the chamber 100 is isolated from the outside by a cover of the chamber 100. Next, in a state where the chuck 200 rotates at high speed, the photoresist resin composition is dropped and coated on the top surface of the optical substrate 10 by the photoresist resin composition supply part 500. Accordingly, a photoresist resin composition layer may be formed on the optical substrate 10.

The method of fabricating the blank mask according to another embodiment includes a step of discharging the process by-products 511, generated from a space between the side surface 12 of the optical substrate 10 and the chuck 200, by the compressed air in the process of forming the photoresist layer 50.

When the photoresist resin composition is coated on the optical substrate 10, the first air pump 300 may supply the compressed air to the by-product removal part 230. Accordingly, the process by-products 511 may be removed from the space 250 between the side surface 12 of the optical substrate 10 and the chuck 200. That is, the process by-products 511 may be discharged by the by-product removal part 230 from the space 250 between the side surface 12 of the optical substrate 10 and the guide part 220.

When the photoresist resin composition is coated on the optical substrate 10, the vacuum part 310 may apply the vacuum to the by-product removal part 230. Accordingly, the process by-products 511 may be removed from the space 250 between the side surface 12 of the optical substrate 10 and the chuck 200. That is, the process by-products 511 may be discharged by the by-product removal part 230 from the space 250 between the side surface 12 of the optical substrate 10 and the guide part 220.

The step of removing the process by-products 511 and the step of rotating the optical substrate 10 at high speed by the chuck 200 may be performed at the same time. That is, the process of forming the photoresist layer 50 and the process of discharging the process by-products 511 may be performed at the same time.

The photoresist resin composition may include a binder resin, a photosensitive resin and an organic solvent.

Examples of the binder resin include novolac resin, phenolic resin, epoxy resin, polyimide resin, and the like. Examples of the binder resin include polyvinyl pyrrolidone, poly(acrylamide-co-diacetoneacrylamide), and the like.

The photosensitive resin may include a photosensitizer.

The photosensitizer may be one or more selected from the group consisting of 4,4′-diazido-2,2′-stilbendisulfonate sodium salt, 4,4′-diazo-2,2′-dibenzalacetone disulfonate disodium salt, 2,5-bis(4-azido-2-sulfobenzylidene) cyclopentanone disodium salt and 4,4′-diazido-2,2′-stilbendisulfonate sodium salt.

The solvent may be selected from one or more of the group consisting of ethyl acetate, butyl acetate, diethylene glycol dimethyl ether, diethylene glycol dimethyl ethyl ether, dipropylene glycol dimethyl ether, methyl methoxypropionate, ethyl ethoxy propionate (EEP), ethyl lactate, propylene glycol methyl ether acetate (PGMEA), propylene glycol methyl ether, propylene glycol propyl ether, methyl cellosolve acetate, ethyl cellosolve acetate, diethylene glycol methyl acetate, diethylene glycol ethyl acetate, acetone, methyl isobutyl ketone, cyclohexanone, dimethylformamide (DMF), N,N-dimethylacetamide (DMac), N-methyl-2-pyrrolidone (NMP), γ-butyrolactone, diethyl ether, ethylene glycol dimethyl ether, diglyme, tetrahydrofuran (THF), methanol, ethanol, propanol, iso-propanol, methyl cellosolve, ethyl cellosolve, diethylene glycol methyl ether, diethylene glycol ethyl ether, dipropylene glycol methyl ether, toluene, xylene, hexane, heptane and octane.

The photoresist resin composition may include about 3 wt % to about 50 wt % of the binder resin, about 2 wt % to about 40 wt % of the photosensitizer, and about 10 wt % to about 94 wt % of the solvent.

The photoresist resin composition may further include an additive such as a leveling agent or an adhesion aid.

Accordingly, the photoresist resin composition layer formed on the optical substrate 10 is dried, and the solvent is removed. Accordingly, the photoresist layer 50 may be formed on the optical substrate 10 as shown in FIG. 13. Accordingly, a blank mask including the optical substrate 10 and the photoresist layer 50 may be fabricated.

Light is selectively irradiated to the photoresist layer 50, and the light-shielding film is selectively etched, thereby forming the light-shielding pattern film 35.

As shown in FIG. 14, a photomask 2 including the light-transmissive substrate 20 and the light-shielding pattern film 35 disposed on the light-transmissive substrate 20 may be formed.

The light-shielding pattern film 35 includes a transition metal and at least one of oxygen and nitrogen.

The light-shielding pattern film 35 may be formed by patterning the light-shielding film 30 of the blank mask 1 as described above.

Descriptions of the physical properties, composition and structure of the light-shielding pattern film 35 are omitted as they overlap with the descriptions of the light-shielding film 30 of the blank mask 1.

A method of fabricating a semiconductor device according to one embodiment includes a step of placing a light source, a photomask 2 and a semiconductor wafer coated with a resist film; an exposure step of selectively transmitting and emitting light, incident from the light source, onto a semiconductor wafer through the photomask 2; and a development step of developing a pattern on the semiconductor wafer.

The photomask 2 includes the light-transmissive substrate 20, and the light-shielding pattern film 35 is disposed on the light-transmissive substrate 20.

The light-shielding pattern film 35 includes a transition metal and at least one of oxygen, nitrogen and carbon.

In the preparation step, the light source is a device capable of generating short-wavelength exposure light. The exposure light may be light having a wavelength of 200 nm. The exposure light may be ArF laser light having a wavelength of 193 nm.

A lens may be additionally disposed between the photomask 2 and the semiconductor wafer. The lens has the function of reducing the circuit pattern shape on the photomask 2 and transferring it onto the semiconductor wafer. The lens is not limited as long as it can be generally applied to an ArF laser light semiconductor wafer exposure process. For example, the lens may be a lens made of calcium fluoride (CaF₂).

In the exposure step, exposure light may be selectively transmitted onto the semiconductor wafer through the photomask 2. In this case, chemical degeneration may occur in a resist film part on which exposure light is incident.

In the development step, the semiconductor wafer that has been subjected to the exposure step may be treated with a developing solution to develop a pattern on the semiconductor wafer. When the applied resist film is a positive resist, a resist film part on which exposure light is incident may be dissolved by the developing solution. When for example the applied resist film is a negative resist, a resist film part on which exposure light is not incident may be dissolved by the developing solution. The resist film is formed into a resist pattern by treatment with the developing solution. A pattern may be formed on the semiconductor wafer using the resist pattern as a mask.

A description of the photomask 2 is omitted as it overlaps with the previous content.

The method of fabricating a blank mask according to one embodiment may minimize adsorption 51 of the droplets on the side surface 12 of the light-transmissive substrate 20. In addition, the method of fabricating a blank mask according to one embodiment may minimize adsorption 52 of the droplets on the lower surface 13 of the light-transmissive substrate 20. That is, the method of fabricating a blank mask according to this embodiment may minimize droplet-type adsorption 51, 52, formed by the droplets, on the side surface 12 and/or lower surface 13 of the light-transmissive substrate 20.

Accordingly, the droplet-type adsorption 51 may not exist on the side surface 12 of the light-transmissive substrate 20. In addition, the droplet-type adsorption 52 may not exist on the lower surface 13 of the light-transmissive substrate 20. That is, the number of the droplet-type adsorption 51, 52 formed on the side surface 12 and lower surface 13 of the light-transmissive substrate 20 may be 0.

Alternatively, as shown in FIGS. 15 and 16, the droplet-type adsorption 51 may be formed on the side surface 12 of the light-transmissive substrate 20.

The droplet-type adsorption 51 may be formed due to liquid droplets adsorbed on the side surface 12 of the light-transmissive substrate 20. The liquid droplets may be the fine particles described above. That is, the photoresist composition is scattered into fine particles and deposited on the side surface 12 of the light-transmissive substrate 20, thereby forming the droplet-type adsorption 51.

In addition, as shown in FIG. 17, the droplet-type adsorption 52 may be formed on the lower surface 13 of the light-transmissive substrate 20.

The droplet-type adsorption 52 may be formed due to the liquid droplets adsorbed on the lower surface 13 of the light-transmissive substrate 20. That is, the photoresist composition is scattered into fine particles and deposits on the lower surface of the light-transmissive substrate 20, thereby forming the droplet-type adsorption 52.

The droplet-type adsorption 51, 52 includes the photoresist composition. It may include substantially the same material as the photoresist layer.

The droplet-type adsorption 51, 52 may have a curved surface. The droplet-type adsorption 51, 52 may have a curved surface formed on the opposite side to the adsorbed surface. The droplet-type adsorption 51, 52 may have an island shape. The diameter DA of the droplet-type adsorption 51, 52 may range from about 0.01 μm to about 10 μm.

On the side surface 12 of the light-transmissive substrate 20, the number of the droplet-type adsorption 51 may be less than about 4 per cm². On the side surface 12 of the light-transmissive substrate 20, the number of the droplet-type adsorption 51 may be less than about 3 per cm². On the side surface 12 of the light-transmissive substrate 20, the number of the droplet-type adsorption 51 may be less than about 2.5 per cm². On the side surface 12 of the light-transmissive substrate 20, the number of the droplet-type adsorption 51 may be less than about 2 per cm². On the side surface 12 of the light-transmissive substrate 20, the number of the droplet-type adsorption 51 may be less than about 1.5 per cm². On the side surface 12 of the light-transmissive substrate 20, the number of the droplet-type adsorption 51 may be less than about 1 per cm².

On the side surface 12 of the light-transmissive substrate 20, a minimum value of the number of the droplet-type adsorption 51 may be about 0.005 per cm².

On the lower surface 13 of the light-transmissive substrate 20, the number of the droplet-type adsorption 52 may be less than about 5 per cm². On the lower surface 13 of the light-transmissive substrate 20, the number of the droplet-type adsorption 52 may be less than about 4 per cm². On the lower surface 13 of the light-transmissive substrate 20, the number of the droplet-type adsorption 52 may be less than about 3.5 per cm². On the lower surface 13 of the light-transmissive substrate 20, the number of the droplet-type adsorption 52 may be less than about 3 per cm². On the lower surface 13 of the light-transmissive substrate 20, the number of the droplet-type adsorption 52 may be less than about 2.5 per cm². On the lower surface 13 of the light-transmissive substrate 20, the number of the droplet-type adsorption 52 may be less than about 2 per cm² On the lower surface 13 of the light-transmissive substrate 20, the number of the droplet-type adsorption 52 may be less than about 1.5 per cm². On the lower surface 13 of the light-transmissive substrate 20, the number of the droplet-type adsorption 52 may be less than about 1 per cm².

On the lower surface 13 of the light-transmissive substrate 20, a minimum value of the number of the droplet-type adsorption 52 may be about 0.005 per cm².

The droplet-type adsorption 51, 52 may include first droplet-type adsorption with a diameter ranging from about 0.01 μm or more and less than about 0.04 μm.

On the side surface 12 of the light-transmissive substrate 20, the number of the first droplet-type adsorption may be less than about 2 per cm². On the side surface 12 of the light-transmissive substrate 20, the number of the first droplet-type adsorption may be less than about 1.8 per cm².

On the side surface 12 of the light-transmissive substrate 20, a minimum value of the number of the first droplet-type adsorption may be about 0.005 per cm².

On the lower surface 13 of the light-transmissive substrate 20, the number of the first droplet-type adsorption may be less than about 2.5 per cm². On the lower surface 13 of the light-transmissive substrate 20, the number of the first droplet-type adsorption may be less than about 2 per cm².

On the lower surface 13 of the light-transmissive substrate 20, a minimum value of the number of the first droplet-type adsorption may be less than about 0.005 per cm².

The droplet-type adsorption 51, 52 may include second droplet-type adsorption with a diameter ranging from about 0.04 μm or more and less than about 0.3 μm.

On the side surface 12 of the light-transmissive substrate 20, the number of the second droplet-type adsorption may be less than about 1 per cm². On the side surface 12 of the light-transmissive substrate 20, the number of the second droplet-type adsorption may be less than about 0.5 per cm².

On the side surface 12 of the light-transmissive substrate 20, a minimum value of the number of the second droplet-type adsorption may be about 0.005 per cm².

On the lower surface 13 of the light-transmissive substrate 20, the number of the second droplet-type adsorption may be less than about 1 per cm². On the lower surface 13 of the light-transmissive substrate 20, the number of the second droplet-type adsorption may be less than about 0.5 per cm².

On the lower surface 13 of the light-transmissive substrate 20, a minimum value of the number of the second droplet-type adsorption may be about 0.005 per cm².

The droplet-type adsorption 51, 52 may include third droplet-type adsorption with a diameter ranging from about 0.3 μm or more and less than about 3 μm.

On the side surface 12 of the light-transmissive substrate 20, the number of the third droplet-type adsorption may be less than about 1 per cm². On the side surface 12 of the light-transmissive substrate 20, the number of the third droplet-type adsorption may be less than about 0.5 per cm².

On the side surface 12 of the light-transmissive substrate 20, a minimum value of the number of the third droplet-type adsorption may be about 0 per cm².

On the lower surface 13 of the light-transmissive substrate 20, the number of the third droplet-type adsorption may be less than about 1 per cm². On the lower surface 13 of the light-transmissive substrate 20, the number of the third droplet-type adsorption may be less than about 0.5 per cm².

On the lower surface 13 of the light-transmissive substrate 20, a minimum value of the number of the third droplet-type adsorption may be about 0 per cm².

The droplet-type adsorption 51, 52 may include fourth droplet-type adsorption with a diameter ranging from about 3 μm or more and less than about 10 μm.

On the side surface 12 of the light-transmissive substrate 20, the number of the fourth droplet-type adsorption may be less than about 1 per cm². On the side surface 12 of the light-transmissive substrate 20, the number of the fourth droplet-type adsorption may be less than about 0.5 per cm².

On the side surface 12 of the light-transmissive substrate 20, a minimum value of the number of the fourth droplet-type adsorption may be about 0 per cm².

On the lower surface 13 of the light-transmissive substrate 20, the number of the fourth droplet-type adsorption may be less than about 1 per cm². On the lower surface 13 of the light-transmissive substrate 20, the number of the fourth droplet-type adsorption may be less than about 0.5 per cm².

On the lower surface 13 of the light-transmissive substrate 20, a minimum value of the number of the fourth droplet-type adsorption may be about 0 per cm².

Since the blank mask according to one embodiment minimizes the droplet-type adsorption 51, 52 as described above, optical distortion may be minimized. In particular, since the blank mask according to one embodiment minimizes relatively large droplet-type adsorption as described above, optical distortion may be further minimized.

The method of fabricating a blank mask according to one embodiment includes a step of removing droplets generated in the step of forming the photoresist layer. Accordingly, the method of fabricating a blank mask according to this embodiment may prevent the side surface 12 and/or lower surface 13 of the light-transmissive substrate 20 from being contaminated by process by-products such as the droplets.

In particular, the method of fabricating a blank mask according to one embodiment may remove droplets, scattered from the photoresist composition for forming the photoresist layer, from the side surface 12 of the light-transmissive substrate 20 using compressed air or a vacuum.

Accordingly, the method of fabricating a blank mask according to one embodiment may effectively prevent the droplets from being adsorbed on the side surface 12 and lower surface 13 of the light-transmissive substrate 20.

Accordingly, the method of fabricating a blank mask according to one embodiment may provide a blank mask in which the number of droplet-type adsorption 51 is less than 3 per cm² on the side surface 12 of the light-transmissive substrate 20. In addition, the method of fabricating a blank mask according to another embodiment may provide a blank mask in which the number of the droplet-type adsorption 52 is less than 4 per cm² on the lower surface 13 of the light-transmissive substrate 20.

Accordingly, the method of fabricating a blank mask according to another embodiment may minimize optical distortion due to the droplet-type adsorption 51, 52. Accordingly, the method of fabricating a blank mask according to this embodiment may provide improved optical performance.

In addition, since the method of fabricating a blank mask according to another embodiment suppresses the droplet-type adsorption 51, 52 as described above, an additional process of removing adsorbed droplets on the side surface 12 and lower surface 13 of the light-transmissive substrate 20 is not used.

Accordingly, the method of fabricating a blank mask according to one embodiment may prevent the photoresist layer from being damaged by an additional process to remove the droplet-type adsorption.

Since the number of the droplet-type adsorption 51, 52 formed on the side surface 12 and lower surface 13 of the light-transmissive substrate 20 of the blank mask according to another embodiment is small, optical distortion may be minimized, and improved optical performance may be provided.

Although the preferred embodiments of the present invention have been described in detail above, the scope of the present invention is not limited thereto, and various modifications and improvements made by those skilled in the art are also within the scope of the present invention.

### Example 1

Resist coating was performed using an 8.5% FEP171 (manufactured by FUJIFILM Arch Co, Ltd) solution. FEP171 is a positron beam resist, and a solvent for the solution is a mixture of propylene glycolmonomethyl ether acetate (PGMEA) and propylene glycol monomethyl ether (PGME) mixed in a ratio of 8 to 2.

A quartz substrate with a size of about 6 inches×about 6 inches was used, and the quartz substrate has a thickness of 0.25 inches. The quartz substrate was seated on a support part and inside a guide part. An interval between the guide part and the quartz substrate was 0.5 mm, and a height difference between the guide part and the quartz substrate was 0.5 mm.

In addition, through holes with a diameter of about 1 mm were placed at a pitch of about 25 mm along the outer edge of the support part. Through the through holes, compressed air was continuously sprayed at a rate of about 3 ml/sec.

After dropping the FEP171 solution on the quartz substrate, the main rotation speed was changed stepwise in a range of about 750 rpm to about 1750 rpm in 250 rpm intervals (5 conditions), and the main rotation time was changed stepwise in 1-second intervals (5 conditions) in a range of 1 to 5 seconds. A drying rotation speed was fixed at 300 rpm.

Accordingly, an optical substrate on which the photoresist layer had been formed was produced.

### Examples 2 to 5 and Comparative Example

As in Table 1 below, the speed of compressed air was adjusted. The remaining processes were performed referring to Example 1.

TABLE 1

| | Compressed air speed |
|---|---|
| Classification | (1 ml/sec) |
| Example 1 | 3 |
| Example 2 | 2 |
| Example 3 | 1.5 |
| Example 4 | 1 |
| Example 5 | 0.5 |
| Comparative example | — |

### Evaluation Example

### 1. Number of Droplet-Type Adsorption

In the optical substrates manufactured in the examples and the comparative example, the number of droplet-type adsorption on the side surface and lower surface of the quartz substrate was measured using an optical surface inspection equipment (M6641S manufactured by LASERTEC).

On the side surface of the quartz substrate, the number of the droplet-type adsorption was derived for each particle diameter as shown in Table 2 below.

TABLE 2
Classification Particle diameter

| | Particle diameter | Particle diameter | Particle diameter | Particle diameter | |
|---|---|---|---|---|---|
| | 0.01 μm~0.04 μm | 0.04 μm~0.3 μm | 0.3 μm~3 μm | 3 μm~10 μm | Sum |
| Classification | (number/cm²) | (number/cm²) | (number/cm²) | (number/cm²) | (number/cm²) |
| Example 1 | 0.02583 | 0.02583 | 0 | 0 | 0.0517 |
| Example 2 | 0.1033 | 0.0775 | 0 | 0 | 0.1808 |
| Example 3 | 0.2583 | 0.05167 | 0 | 0 | 0.31 |
| Example 4 | 0.8008 | 0.05167 | 0 | 0 | 0.8525 |
| Example 5 | 1.4983 | 0.05167 | 0 | 0 | 1.55 |
| Comparative | 4.5983 | 7.0267 | 1.6017 | 0.05167 | 13.28 |
| example | | | | | |

On the lower surface of the quartz substrate, the number of the droplet-type adsorption was derived for each particle diameter as shown in Table 2 below.

TABLE 3

| | Particle diameter | Particle diameter | Particle diameter | Particle diameter | |
|---|---|---|---|---|---|
| | 0.01 μm~0.04 μm | 0.04 μm~0.3 μm | 0.3 μm~3 μm | 3 μm~10 μm | Sum |
| Classification | (number/cm²) | (number/cm²) | (number/cm²) | (number/cm²) | (number/cm²) |
| Example 1 | 0.0258 | 0.0129 | 0 | 0 | 0.03775 |
| Example 2 | 0.0947 | 0.0603 | 0.0043 | 0.0043 | 0.1636 |
| Example 3 | 0.2626 | 0.0344 | 0 | 0 | 0.2971 |
| Example 4 | 0.80 | 0.0431 | 0 | 0 | 0.8439 |
| Example 5 | 1.494 | 0.0603 | 0.0086 | 0 | 1.5629 |
| Comparative | 4.590 | 7.014 | 1.0419 | 0.0861 | 12.731 |
| example | | | | | |

As shown in Tables 2 and 3, on the optical substrates according to the examples, the number of droplet-type adsorption was very small, and there were almost no edge beads.

### DESCRIPTION OF SYMBOLS

chamber 100
chuck 200
first air pump 300
exhaust part 400
photoresist resin composition supply part 500
second air pump 600
air sweep part 610

1. A method of fabricating a blank mask, the method comprising:
forming a light-shielding film on a light-transmissive substrate to form an optical substrate;
forming a photoresist layer on the light-shielding film; and
removing droplets, generated in the forming of the photoresist layer, from a side surface of the light-transmissive substrate,
wherein the number of droplet-type adsorption, derived from the droplets, on the side surface of the light-transmissive substrate, is less than 3 per cm².

2. The method according to claim 1, further comprising seating the optical substrate on a chuck,
wherein the forming of the photoresist layer comprises:
dropping a photoresist composition on the light-shielding film;
rotating the optical substrate; and
spraying compressed air between the optical substrate and the chuck,
wherein the rotating of the optical substrate and the spraying of the compressed air are simultaneously performed.

3. The method according to claim 2, wherein the chuck comprises:
a support part for supporting the optical substrate; and
a guide part disposed on a side surface of the optical substrate,
wherein in the rotating of the optical substrate, the optical substrate and the guide part are simultaneously rotated, and
the compressed air is sprayed between the guide part and the side surface of the optical substrate.

4. The method according to claim 1, further comprising seating the optical substrate on a chuck,
wherein the forming of the photoresist layer comprises:
dropping a photoresist composition on the light-shielding film;
rotating the optical substrate; and
applying vacuum between the side surface of the optical substrate and the chuck,
wherein the rotating of the optical substrate and the applying of the vacuum e are simultaneously performed.

5. The method according to claim 4, wherein the chuck comprises:
a support part for supporting the optical substrate; and
a guide part disposed on the side surface of the optical substrate,
wherein in the rotating of the optical substrate, the optical substrate and the guide part are simultaneously rotated, and
the vacuum is applied between the guide part and the side surface of the optical substrate.

6. The method according to claim 1, wherein the number of the droplet-type adsorption formed on a lower surface of the light-transmissive substrate is less than 4 per cm².

7. The method according to claim 1, wherein the optical substrate comprises the droplet-type adsorption,
the droplet-type adsorption has an island shape, and
the droplet-type adsorption has a diameter ranging from about 0.01 μm to about 10 μm.

8. The method according to claim 7, wherein the number of the droplet-type adsorption formed on a side surface of the light-transmissive substrate ranges from about 0.05 per cm² to about 1 per cm².

9. A blank mask, comprising:
a light-transmissive substrate;
a light-shielding film disposed on the light-transmissive substrate; and
a photoresist layer disposed on the light-shielding film and comprising a photosensitive resin, and
on a side surface of the light-transmissive substrate, the number of droplet-type adsorption comprising the photosensitive resin is less than 3 per cm².

10. The blank mask according to claim 9, wherein the number of the droplet-type adsorption formed on a lower surface of the light-transmissive substrate is less than 4 per cm².

11. The blank mask according to claim 9, wherein the number of the droplet-type adsorption formed on a side surface of the light-transmissive substrate is less than 2.5 per cm².

12. The blank mask according to claim 11, wherein the number of the droplet-type adsorption formed on the side surface of the light-transmissive substrate is less than 0.5 per cm².

13. The blank mask according to claim 10, wherein the number of the droplet-type adsorption formed on a lower surface of the light-transmissive substrate is less than 2 per cm².

14. The blank mask according to claim 9, wherein the droplet-type adsorption has a diameter ranging from 0.01 μm to 10 μm.

15. A blank mask, comprising:
a light-transmissive substrate;
a light-shielding film disposed on the light-transmissive substrate;
a photoresist layer disposed on the light-shielding film and comprising a photosensitive resin; and
a droplet-type adsorption formed on a side surface of the light-transmissive substrate, comprising the photosensitive resin and having an island shape,
wherein the droplet-type adsorption formed on the side surface of the light-transmissive substrate has a density ranging from about 0.05 pieces per cm2to about 3 pieces per cm².

16. The blank mask according to claim 15, wherein the droplet-type adsorption is formed on a lower surface of the light-transmissive substrate, and
the droplet-type adsorption formed on the lower surface of the light-transmissive substrate has a density ranging from about 0.05 pieces per cm² to about 3 pieces per cm².

17. The blank mask according to claim 16, wherein the droplet-type adsorption comprises first droplet-type adsorption having a diameter ranging from about 0.01 μm to about 0.04 μm, and the number of the first droplet-type adsorption ranges from about 0.05 per cm² to about 0.5 per cm².

18. The blank mask according to claim 17, wherein the droplet-type adsorption comprises second droplet-type adsorption having a diameter ranging from about 0.04 μm to about 0.3 μm, and
the number of the second droplet-type adsorption ranges from about 0.05 per cm² to about 0.5 per cm².

19. The blank mask according to claim 18, wherein the droplet-type adsorption comprises third droplet-type adsorption having a diameter ranging from about 0.3 μm to about 3 μm, and the number of the third droplet-type adsorption ranges from about 0.05 per cm² to about 0.5 per cm².

20. The blank mask according to claim 15, wherein the droplet-type adsorption formed on a side surface of the light-transmissive substrate has a density ranging from about 0.05 pieces per cm² to about 1 piece per cm².
